(19) United States
(12) Patent Application Publication
(10) Pub. No.: US 2010/0040245 A1
(43) Pub. Date: Feb. 18, 2010

(54) MULTI-FUNCTION HEADSET AND FUNCTION SELECTION OF SAME

(75) Inventors: Vincentius Paulus Buil, Eindhoven (NL); Elmo Marcus Attila Diederiks, Eindhoven (NL); Tatiana Aleksandrovna Lashina, Eindhoven (NL); Johannes Antonius Jansen, Utrecht (NL); Ramon Eugene Franciscus Van De Ven, Eindhoven (NL); Gerrot Hollemans, Helmond (NL); Sander Bernard Francis Van De Wijdeven, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., EINDHOVEN (NL)

(21) Appl. No.: 12/303,295

(22) PCT Filed: Jun. 11, 2007
(86) PCT No.: PCT/IB07/52196

§ 371 Date: Jul. 8, 2009

Related U.S. Application Data
(60) Provisional application No. 60/812,351, filed on Jun. 9, 2006.

(51) Int. Cl. H03G 3/00; H04R 25/00

(52) U.S. Cl. 381/107; 381/375

(57) ABSTRACT

A multi-function headset is disclosed. The multi-function headset includes an ear shell attached to one end of a holding means the ear shell comprising a speaker unit through which audio stimulus is provided to a user, a microphone attached on a first end of a boom assembly and engaging an engagement switch on a second end of said boom assembly with the ear shell, the engagement switch position selecting an application of the head set. In another aspect of the invention, the ear shell further comprises a first switch engaging the boom assembly when the boom assembly is in a retracted position. In another embodiment of the invention, a headset including an ear shell attached to one end of a holding means is disclosed. The ear shell comprising a speaker unit through which audio stimulus is provided to a user, and means for adjusting a volume through the speaker unit wherein the means is selected from the group consisting of: pressure determining sensors and switches.

This invention relates to the field of customer devices and more specifically to a multi-function headset and function selection of same.

Wired and wireless headsets are well-known art. Wired headsets, which have been used as audio headsets and telephone headsets, are being replaced with wireless headsets performing the similar functions. For example, Bluetooth technology headsets are entering the market and are being used with cellular telephones and MP3 players.

However, the conventional headsets lack feedback to show others whether the person hearing a headset is on the phone or listening to music. This can make a difference when another person wants to address a person using a headset, as the person may be on a phone call and it is socially unacceptable to interrupt a phone conversion.

Furthermore, the headsets include a plurality of controls that are confusing and lack an intuitive way of selecting a specific function or operation as a single button may initiate one or more functions. For example, many headsets often have volume controller integrated into one of the ear shells in the form of a dial, knob or button. Another method of controlling the volume may be implemented using head nodding or voice control or touching of tapping on the headset ear shell. See for example, commonly-owned U.S. patent application Ser. No. 10/552,769, entitled, “Personal audio system with earpiece remote controller”, filed on Oct. 12, 2005, (PHNL 030392).

U.S. patent application Ser. No. 10/552,769, entitled “Personal audio system with earpiece remote controller” describes a technology that can be used to sense whether headset ear shells are pressed to the ears, worn normally or lifted from the ears. By measuring the impedance level of the loudspeakers in the headset, it is possible to detect how much air-resistance they encounter when playing sound. When the headset is pressed to the ears this air-resistance is higher than when normally worn which is higher than when the headset is not worn at all. The difference in air-resistance creates a significant difference in measured impedance of the speaker driver. However, this technology requires sound to be played over the speakers for sensing the impedance difference.

Existing solutions for operating headsets to select a particular application and control functions in the selected application are not optimal in terms of ease of use as (1) dial, knobs or buttons must be searched where only peripheral and tactile senses can be used, (2) gestures, head-nodding requires the user to remember which actions are needed to control which functions, (3) voice control is difficult due to the discrete character of speech and (4) touch/taping requires remembering the touch tapping patterns used to select a function.

Hence, there is a need in the industry for a multi-function headset and simplified control of same.

A multi-function headset is disclosed. The multi-function headset includes an ear shell attached to one end of a holding means the ear shell comprising a speaker unit through which audio stimulus is provided to a user, a microphone attached on a first end of a boom assembly and an engagement switch on a second end of said boom assembly within the ear shell, the engagement switch position selecting an application of the head set. In another embodiment of the invention, the ear shell further comprises a first switch engaging the boom assembly when the boom assembly is in a retracted position. In another embodiment of the invention, a headset including an ear shell attached to one end of a holding means is disclosed. The ear shell comprising a speaker unit through which audio stimulus is provided to a user; and means for adjusting a volume through said speaker unit wherein said means is selected from the group consisting of: pressure determining sensors and switches.

The advantages of the present invention may be better understood by referring to the following description taken into conjunction with the accompanying drawings in which:

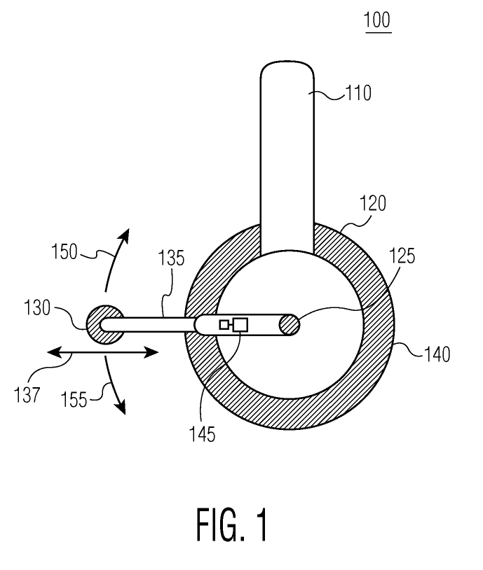

FIG. 1 illustrates a multi-function headset in accordance with the principles of the invention;

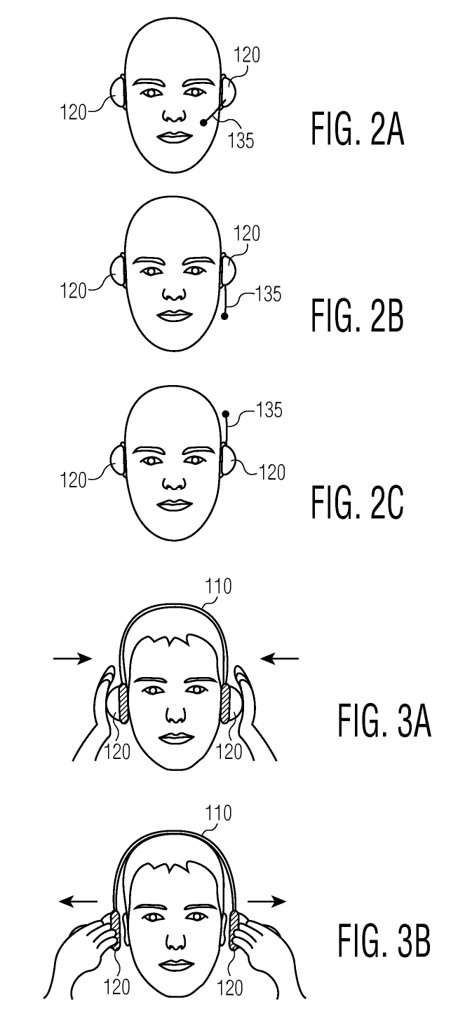

FIGS. 2A-2C illustrate examples of selecting an application of the multi-function headset in accordance with the principles of the invention;

FIGS. 3A-3B illustrate examples of controlling functions of the selected application in accordance with the principles of the invention; and

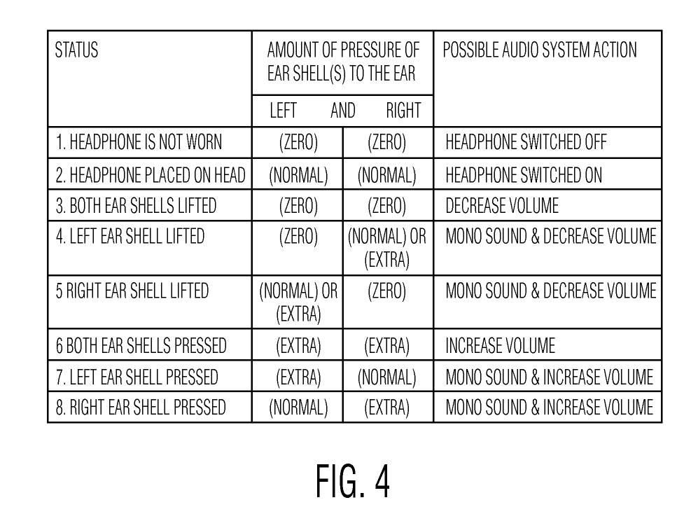

FIG. 4 illustrate exemplary operations in accordance with the principles of the invention.

It is to be understood that these drawings are solely for purposes of illustrating the concepts of the invention and are not intended as a definition of the limits of the invention. The embodiments shown in the figures herein and described in the accompanying detailed description are to be used as illustrative embodiments and should not be construed as the only manner of practicing the invention. Also, the same reference numerals, possibly supplemented with reference characters where appropriate, have been used to identify similar elements.

FIG. 1 illustrates a side-view of an exemplary embodiment of a headset in accordance with the principles of the invention. In this exemplary embodiment, a ear shell unit 120 is attached to a headband 110 that when placed on a user's head allows the illustrated ear shell 120 to be in contact with the user's ear. The headband 110 may be adjustable to allow for a comfort fit of the ear shell 120 with regard to the ear. Although not shown it would be recognized that head sets 100 may be fabricated using a single ear shell or with dual ear shells. In the former case, the headband 110 may also be an ear loop that is attached to the ear rather than being placed on the head. In addition, in the dual ear shell head set, an ear shell 120 is attached to each of the ends of the headband 110. Ear shell 120 includes speaker 140 which is placed adjacent to the ear channel to enable sound received by the head set 100 to be transmitted to the user.

Also shown attached to ear shell 120 is retractable boom/antenna 135 that includes a microphone 130 on one end and engages a retraction switch 145 in ear shell 120 when boon/antenna is retracted. Retraction switch 145 provides a means for determining the relative position of microphone 130 with respect to ear shell 120. With reference to the arrow 137, boom/antenna 135 may be drawn closer to or extended further away from ear shell 120. When the microphone is extended away from ear shell 120 the retraction switch is disengaged. Also shown is rotary switch 125 contained with ear shell 120. Rotary switch 125 provides means for determining the relative orientation of boom/antenna 135 with respect to ear shell 120. For example, boom/antenna 135 may be extended in a plane directly outward from ear shell 120 or may be lifted up, arrow 150 or pressed down, arrow 155 from the plane. Accordingly, switches 125 and 145 may be used to activate/deactivate specific applications or functions associated with head set 100. For example, in a preferred embodiment of the invention, when boom/antenna 135 is drawn towards ear shell 120 head set 100 may be in an “off” state and when boom/antenna 135 is extended head set 100 is placed in an activate or “on” state. Although switch 125 is shown and discussed with regard to a rotary switch, it would be recognized that switch 125 may similarly be selected as a multi-position linear switch, a depression switch, or any other type of switch.

FIGS. 2A-2C collectively illustrate examples of the selection of an application based on the position of boom/antenna 135. FIG. 2A illustrates the position of boom/antenna 135 in an extended state and positions microphone 130 close to the user's mouth. In this position, the head set 100 may be used to select a telephone application. In the telephone application microphone 130 is enabled and antenna 135 is disabled. FIG. 2B illustrates the position of boom/antenna 135 in a down-position. In this position an exemplary passive audio (listening to music or other recorded material) application may be selected. In passive audio listening application microphone and antenna are disabled. FIG. 2C illustrates boom/antenna 135 in an up-position. In this position an exemplary radio application may be selected and microphone 130 is disabled while antenna 135 is enabled. In one aspect of the invention, the extension of boom/antenna 135 would enable microphone 130, while lifting or depressing boom/antenna would enable the antenna or the listening ability. Table 1 illustrates exemplary operations based on the position of the boom/antenna 135.

| | | | Listening |
|---|---|---|---|
| Boom/antenna Pos. | Microphone | Antenna | Device |
| Extended in-plane | Enabled | Disabled | Disabled |
| Extended up | Disabled | Enabled | Disabled |
| Extended down | Disabled | Disabled | Enabled |
| Retracted in-plane | Disabled | Disabled | Enabled |
| Retracted up* | Disabled | Enabled | Disabled |
| Retracted down* | Disabled | Disabled | Enabled |

*optional setting

In another aspect of the invention, control of the head set 100, volume may be performed by pressing/releasing the ear shells to/from the ears. FIGS. 3A and 3B illustrate examples of increasing and decreasing volume, respectively, in accordance with one aspect of the invention. FIG. 3A illustrates a user pressing on the ear shells 120, which causes the volume to be increased. FIG. 3B illustrates a user separating the ear shell 120, which causes the volume to be decreased. Based on factors such as impedance sensing, as disclosed in U.S. patent application Ser. No. ______, filed on (PHNL 050011), pressure sensors, light sensors, or by a switch (other than 125 or 145), the headphone can sense whether one or both ear shells are pressed to or released from the ear.

It would be recognized that in this aspect of the invention, the volume is increased or decreased independent of the position of boom/antenna 135 (other than for the retracted in-place position).

The combination of the signals produced by pressing or separating the ear shell 120 results in the states listed in FIG. 4. State 1 represents the state wherein the headphone 100 is not worn and switched off. State 2 represents the state when the headphone is worn by the user, and the headphone is or may be switched on automatically. In state 2, actions, such as movement of the boom/antenna 135, are interpreted to place the headphone 100 in an operational state. State 3 represents the case when both ear shells are lifted from the ears (FIG. 3B). In this case, pressure with the ear shell 120 is decreased, and as a result the volume setting may be decreased. States 4 and 5 represent the cases wherein either the left or the right ear shell is lifted. In these cases, the pressure within the lifted ear shell is reduced while the pressure in the other may remain the same or be increased. Accordingly, the volume of the lifted ear shell is decreased. State 6 represents the case wherein both ear shells are pressed and the volume in both ear shells is increased based on the detected increase in pressure. States 7 and 8 represent the states when the left or right ear shell, respectively, is pressed and volume increases in the appropriate ear shell. The sequence of taking off the headphone is from state 3, via a time-out, to state 1: when both earpieces measure zero pressure for, a known period of time, e.g., 5 seconds, the volume level is decreased to the minimal level, and the headphone assumes it has been taken off. In this case, the headphone 100 transitions from state 3 to state 1. At that time, the last volume change may be ignored and reset, and the headphone may be switched off automatically. Alternatively, extra sensors, such as IR proximity sensors or touch sensors, may be used to discriminate whether the headphone is worn or not.

Alternatively, lifting one ear shell while pressing the other ear shell can be mapped to a change in the left/right audio balance. Lifting left while pressing right, for example, would decrease the volume in the left ear shell while increasing the volume of in the right ear shell. Although the example of headset volume control is described with regard to dual ear shell head set it would be recognized that the method for volume control described herein is also suitable for a single ear shell headset.

Note that the pressure sensors in the described embodiment may also be used to detect short pressure pulsations caused by tapping on the ear shells. These pulses, e.g. single tap, double, tap etc., can then be used to control playback functions such as play/pause and next/previous track, as described in commonly-owned U.S. patent application Ser. No. 10/552,769, entitled, “Personal audio system with earpiece remote controller”, filed on Oct. 12, 2005, (PHNL 030392). In another aspect of the invention, the mode of operation may be remotely determined. For example, the switch for extending or retracing the boom assembly may be remotely activated by control means on an external device, e.g., mp3 player. Similarly, the microphone may be turned on or off, the volume may be increased or decreased or the position of the boom assembly may be controlled by one or more external controls. As would be recognized, the external controls may use wireless or wired transmission means to communicate control signals to the headset.

As used herein, ear shell 120 include one or more control units or processors such as general purpose or special purpose computer system that execute computer instructions to implement and responds to the stimuli, extend boom, lift boom, depress boom, push ear shell, lift ear shell, etc. Or the processor(s) may be a hardware configuration, such as a dedicated logic circuit or integrated circuit. For example, the processor(s) may selected from a group dedicated hardware such as Programmable Array Logic (PAL), Application Specific Integrated Circuit (ASIC), Field Programmable Gate Array (FPGA), etc., which may be hardware “programmed” to include software instructions or code that provides a known output in response to known inputs. In one aspect, hardware circuitry may be used in place of, or in combination with, software instructions to implement the invention. The elements may also be implemented as discrete hardware elements that are operable to perform the operations shown using coded logical operations or by executing hardware executable code. Memories may be any semiconductor memory, such as PROM, EPROM, EEPROM or RAM, that is external to a processor and/or may be integrated with processor, i.e., cache. Similarly, ear shell 120 may include pressure sensors and/or touch sensors that provide information to the processor to execute the operations shown herein.

While there has been shown, described, and pointed out fundamental novel features of the present invention as applied to preferred embodiments thereof, it will be understood that various omissions and substitutions and changes in the apparatus described, in the form and details of the devices disclosed, and in their operation, may be made by those skilled in the art without departing from the spirit of the present invention. It is expressly intended that all combinations of those elements that perform substantially the same function in substantially the same way to achieve the same results are within the scope of the invention. Substitutions of elements from one described embodiment to another are also fully intended and contemplated.

1. A multi-function headset including an ear shell attached to one end of a holding means said multi-function head set comprising:
a speaker unit through which audio stimulus is provided to a user; and
a microphone attached on a first end of a boom assembly and engaging a engagement switch at a second end of said boom assembly within the ear shell, said engagement switch position selecting an application of the headset.

2. The headset as recited in claim 1, wherein the application is selected from the group consisting of: telephone, radio and audio listening device.

3. The headset as recited in claim 1, wherein said ear shell further comprising:
sensors for determining a pressure within the ear shell and adjusting the audio volume or another parameter provided through said speaker unit based on the determined pressure.

4. The headset as recited in claim 3, wherein the audio volume or other parameter varies as the determined pressure varies.

5. The headset as recited in claim 1, wherein said boom assembly is retractable/extendable.

6. The headset as recited in claim 5, further comprising:
a retraction switch, in said ear shell, engaging said boom assembly when said boom assembly is in a retracted position.

7. The headset as recited in claim 1, wherein said holding means is selected from the group consisting of: headband, neckband, and ear loop.

8. The headset as recited in claim 1, wherein said headset incorporates technology selected from the group consisting of: Bluetooth, RF, and wired.

9. A headset including an ear shell attached to one end of a holding means, said ear shell comprising:
a speaker unit through which audio stimulus is provided to a user; and
means for adjusting a volume through said speaker unit wherein said means is selected from the group consisting of pressure determining sensors and switches.

10. The headset as recited in claim 9, wherein said audio volume through said speaker unit is adjusted in proportion to said means.

11. The headset as recited in claim 9, wherein said ear shell further comprising:
a microphone attached to an extendable/retractable boom assembly on a first end, and
an engagement switch attached to a second end of said extendable/retractable boom assembly, said engagement switch position selecting an application of the headset.

12. The head set as recited in claim 11, wherein the application is selected from the group consisting of: telephone, radio and audio listening device.

13. The head set as recited in claim 12, wherein said ear shell further comprising:
a retraction switch engaging said boom assembly when said boom assembly is in a retracted position.

14. The headset as recited in claim 1, wherein said engagement switch is selected from the group consisting of: rotary switch, linear switch and depression switch.

15. The headset as recited in claim 11, wherein said engagement switch is selected from the group consisting of: rotary switch, linear switch and depression switch.

16. A multi-function headset including an ear shell attached to one end of a holding means, said ear shell comprising:
a speaker unit through which audio stimulus is provided to a user; and
sensors for determining a pressure within the ear shell and adjusting the audio volume or another parameter provided through said speaker unit based on the determined pressure.

17. A multi-function headset including an ear shell attached to each end of a holding means said multi-function head set comprising:
a speaker unit through which audio stimulus is provided to a user; and
a microphone attached on a first end of a boom assembly and engaging a engagement switch at a second end of said boom assembly within one of said ear shells, said engagement switch position selecting an application of the headset.

18. The headset as recited in claim 17, wherein the application is selected from the group consisting of: telephone, radio and audio listening device.

19. The headset as recited in claim 17, wherein said ear shells further comprising:
means for adjusting a volume through said speaker unit wherein said means is selected from the group consisting of: pressure determining sensors and switches.

20. The headset as recited in claim 19, wherein the audio volume or other parameter varies as the determined pressure varies.

21. The headset as recited in claim 17, wherein said boom assembly is retractable/extendable.

22. The headset as recited in claim 21, further comprising:
a retraction switch, in said ear shell, engaging said boom assembly when said boom assembly is in a retracted position.

23. The headset as recited in claim 1, further comprising:
means for receiving control signals for operating the engagement switch.

24. The head set as recited in claim 6, further comprising:
means for receiving control signals for operating the retraction switch.

25. The headset as recited in claim 9, further comprising:
means for receiving control signals for operating the volume.

26. The head set as recited in claim 11, further comprising:
means for receiving control signals for operating the engagement switch.

27. The head set as recited in claim 11, further comprising:
means for receiving control signals for operating the retraction switch.

28. The headset as recited in claim 19, further comprising:
means for receiving control signals for operating the volume.

29. The head set as recited in claim 17, further comprising:
means for receiving control signals for operating the engagement switch.

30. The head set as recited in claim 22, further comprising:
means for receiving control signals for operating the retraction switch
